(19) United States
(12) Patent Application Publication
(10) Pub. No.: US 2026/0267185 A1
(43) Pub. Date: Sep. 10, 2026

(54) DISPLAY DEVICE AND ELECTRONIC DEVICE USING THE SAME

(71) Applicant: Samsung Display Co., Ltd., Yongin-si (KR)

(72) Inventors: Su Jung HUH, Yongin-si (KR); Yong Jo Kim, Yongin-si (KR); Dae Young Lee, Yongin-si (KR); Tae Ho Lee, Yongin-si (KR)

(73) Assignee: Samsung Display Co., Ltd., Yongin-si (KR)

(21) Appl. No.: 19/540,052

(22) Filed: Feb. 13, 2026

(30) Foreign Application Priority Data
Mar. 4, 2025 (KR) 10-2025-0027390

(51) Int. Cl. G02F 1/1335; G06F 3/041; G06F 3/044

(52) U.S. Cl. CPC G02F 1/133512; G06F 3/0412; G06F 3/0446

(57) ABSTRACT

A display device may include a display panel displaying an image by combining or selecting an image of a wide viewing angle and an image of a narrow viewing angle, and a display driving circuit controlling an image display operation of image display pixels in the display panel, wherein the display panel includes a display unit displaying an image through subpixels for each first unit pixel and subpixels for each second unit pixel, a light emission direction control layer on the display unit to vary an emission direction of image display light emitted from the display unit to a front surface, and a black matrix on the light emission direction control layer at positions corresponding to a peripheral area of each first unit pixel, a peripheral area of each second unit pixel, and an area between the subpixels for each second unit pixel, in a mesh structure.

### CROSS-REFERENCE TO RELATED APPLICATION

This application claims priority from Korean Patent Application No. 10-2025-0027390 filed on Mar. 4, 2025 in the Korean Intellectual Property Office and all the benefits accruing therefrom under 35 U.S.C. 119, the contents of which in its entirety are herein incorporated by reference.

### BACKGROUND

### Technical Field

The present disclosure relates to display devices and/or electronic devices using the same.

### Description of the Related Art

With the advancement of the information age, the demand for a display device for displaying an image has increased with various forms. The display device may be a display device such as a liquid crystal display device, a field emission display device and a light emitting display device. The light emitting display device may include an organic light emitting display device including an organic light emitting diode element as a light emitting element, or an inorganic light emitting display device including an inorganic light emitting diode element as a light emitting element.

Recently, there has been an increasing demand from customers to control a viewing angle of an image displayed on a display device. For example, it is desired to control a viewing angle of a passenger display device or a vehicle display device so as not to interfere with driving of a vehicle driver. In addition, the need to control the viewing angle of the display device is also emerging to protect the privacy of passengers using public transportation.

In order to narrow the viewing angle, image display light emitted in lateral and diagonal directions of the display device may need to be partially blocked or the amount of light may need to be reduced. However, when blocking the light or reducing the amount of light, overall brightness and/or luminance of the image may deteriorate.

### SUMMARY

Some example embodiments of the present disclosure provide display devices and/or electronic devices using the same, in which an image of a relatively wide viewing angle or a relatively narrow viewing angle may be selectively displayed using pixels for respectively implementing the relatively wide viewing angle and the relatively narrow viewing angle.

Some example embodiments of the present disclosure provide display devices and/or electronic devices using the same, which include a light emission direction control layer including condensing lenses and configured to control an image display light emission direction of pixels for implementing a relatively narrow viewing angle.

Example embodiments of the present disclosure are not limited to those mentioned above and additional example embodiments of the present disclosure, which are not mentioned herein, will be clearly understood by those skilled in the art from the following description of the present disclosure.

According to an example embodiment of the disclosure, a display device may include a display panel configured to display an image by combining or selecting an image of a relatively wide viewing angle and an image of a relatively narrow viewing angle, and a display driving circuit configured to control an image display operation of image display pixels included in the display panel, wherein the display panel includes a display unit configured to display an image through subpixels for each of a plurality of first unit pixels and subpixels for each of a plurality of second unit pixels, a light emission direction control layer on the display unit and configured to vary an emission direction of image display light emitted from the display unit to a front surface of the display panel, and a black matrix arranged on the light emission direction control layer at positions corresponding to a first peripheral area of each of the first unit pixels, a second peripheral area of each of the second unit pixels, and an area between the subpixels for each of the second unit pixels, in a mesh structure.

According to an example embodiment of the disclosure, a display device may include a display panel configured to display an image by combining or selecting an image of a relatively wide viewing angle and an image of a relatively narrow viewing angle, a display driving circuit configured to control an image display operation of image display pixels included in the display panel, and a touch driving circuit configured to drive touch electrodes of the display panel and detect touch position coordinates of a touch input device or a user, wherein the display panel includes a display unit configured to display an image through subpixels for each of a plurality of first unit pixels and subpixels for each of a plurality of second unit pixels, a light emission direction control layer on the display unit and configured to vary an emission direction of image display light emitted from the display unit to a front surface of the display panel, a touch sensing unit including the touch electrodes, being on the light emission direction control layer, and configured to sense a touch position of the touch input device or the user, and a black matrix on the light emission direction control layer at positions in corresponding to a first peripheral area of each of the second unit pixels, a second peripheral area of each of the first unit pixels, and an area between the subpixels for each of the second unit pixels, in a mesh structure.

According to an example embodiment of the disclosure, an electronic device may include a display device configured to display an image, an image signal processor configured to control an image display timing of the display device, and power supply circuitry configured to provide a power signal to the display device, wherein the display device includes a display panel configured to display an image by combining or selecting an image of a relatively wide viewing angle and an image of a relatively narrow viewing angle, and a display driving circuit configured to control an image display operation of image display pixels included in the display panel, and wherein the display panel includes a display unit configured to display an image through subpixels for each first unit pixel and subpixels for each second unit pixel, a light emission direction control layer on the display unit and configured to vary an emission direction of image display light emitted from the display unit to a front surface of the display panel, and a black matrix on the light emission direction control layer at positions corresponding to a first peripheral area of each first unit pixel, a second peripheral area of each second unit pixel, and an area between the subpixels for each second unit pixel.

In the display device and the electronic device using the same according to the above example embodiments of the present disclosure, an image may be displayed using pixels that implement a wide viewing angle and a narrow viewing angle, respectively, and an image of the narrow viewing angle may be displayed using pixels for implementing the narrow viewing angle when a privacy mode is driven.

Also, in the display device and the electronic device using the same according to one example embodiment, an image display light emission direction of pixels for implementing the narrow viewing angle may be controlled toward a front surface, so that brightness and luminance of images for implementing the narrow viewing angle may be improved.

The effects according to the example embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail some example embodiments thereof with reference to the attached drawings, in which:

FIG. 1 is a plan view illustrating a configuration of a display device according to one example embodiment of the present disclosure;

FIG. 2 is a detailed side cross-sectional view illustrating the display device shown in FIG. 1;

FIG. 3 is a schematic layout view illustrating an example of a display panel according to one example embodiment;

FIG. 4 is a schematic layout view illustrating an example of a touch sensing unit according to one example embodiment;

FIG. 5 is a plan view partially illustrating a subpixel arrangement structure of a display area, according to one example embodiment;

FIG. 6 is a brief cross-sectional view illustrating a cross-sectional structure of line B-B′ of FIG. 5, according to one example embodiment;

FIG. 7 is a cross-sectional view illustrating an emission direction of image display light emitted from first to fourth subpixels included in a first unit pixel of FIG. 6 by arrows;

FIG. 8 is a brief cross-sectional view illustrating a cross-sectional structure of line A-A′ of FIG. 5 according to the first embodiment;

FIG. 9 is a view illustrating a method of forming condensing lenses and a low refractive polymer material layer of a light emission direction control layer shown in FIG. 8;

FIG. 10 is a cross-sectional view illustrating an emission direction of image display light emitted from first to fourth subpixels included in a second unit pixel of FIG. 8 by arrows;

FIG. 11 is a brief cross-sectional view illustrating a cross-sectional structure of line A-A′ of FIG. 5 according to the second example embodiment;

FIG. 12 is a brief cross-sectional view illustrating a cross-sectional structure of line A-A′ of FIG. 5 according to the third example embodiment;

FIG. 13 is a brief cross-sectional view illustrating a cross-sectional structure of line A-A′ of FIG. 5 according to the fourth example embodiment;

FIG. 14 is a brief cross-sectional view illustrating a cross-sectional structure of line A-A′ of FIG. 5 according to the fifth example embodiment;

FIG. 15 is a block diagram illustrating an electronic device including a display device according to one example embodiment of the present disclosure; and

FIG. 16 illustrates schematic diagrams of electronic devices according to various example embodiments.

### DETAILED DESCRIPTION

The present disclosure will now be described more fully hereinafter with reference to the accompanying drawings, in which some example embodiments of the disclosure are shown. This disclosure may, however, be embodied in different forms and should not be construed as limited to the disclosed example embodiments set forth herein. Rather, the example embodiments are provided so that this disclosure will be thorough and complete, and will filly convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Each of the features of the various example embodiments of the present disclosure may be combined with each other, in part or in whole, and technically various interlocking and driving are possible. Each example embodiment may be implemented independently of each other or may be implemented together in an association.

Hereinafter, some example embodiments will be described with reference to the accompanying drawings.

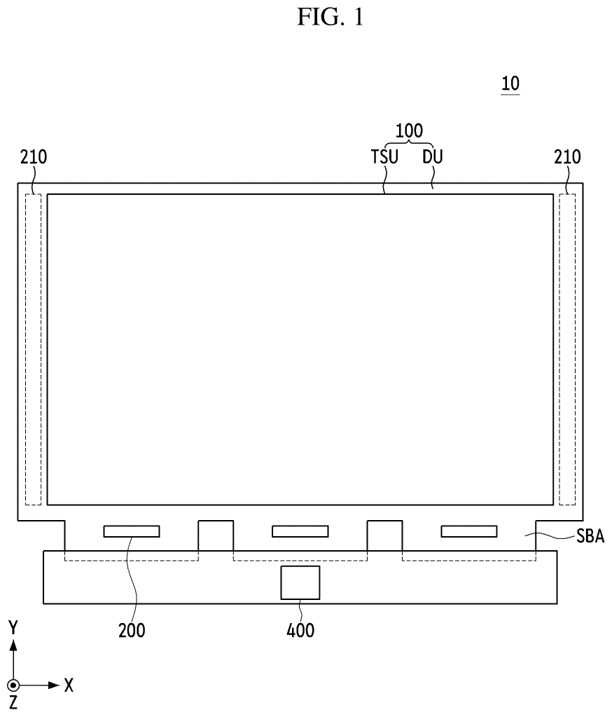

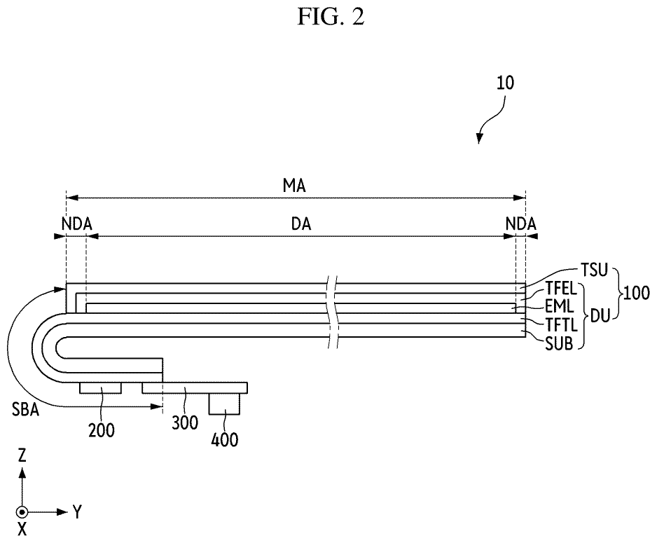

FIG. 1 is a plan view illustrating a configuration of a display device according to one example embodiment of the present disclosure. FIG. 2 is a detailed side cross-sectional view illustrating the display device shown in FIG. 1.

Referring to FIGS. 1 and 2, a display device 10 according to one example embodiment may be classified variously depending on a display manner. For example, the display device may be classified into and include an organic light emitting display (OLED) device, an inorganic light emitting display device, a quantum dot light emitting display (QED) device, a micro-LED display device, a nano-LED display device, a plasma display device (PDP), a field emission display (FED) device, a liquid crystal display (LCD) device, and an electrophoretic display (EPD) device. Hereinafter, the organic light emitting display device will be described as the display device by way of example, and will simply be abbreviated as the display device 10 unless desired to be more specially classified. The display device 10 according to example embodiments are not limited to the organic light emitting display device, and another display device listed as above or known in this art may be applied to example embodiments within the range of technical spirits.

The display device 10 according to one example embodiment may be applied to a portable electronic device such as a mobile phone, a smart phone, a tablet personal computer (PC), a mobile communication terminal, an electronic diary, an electronic book, a portable multimedia player (PMP), a navigator, and an ultra mobile PC (UMPC). For example, the display device 10 may be applied to a television, a laptop computer, a monitor, an advertising board, or Internet of Things (IoT) as a display unit. For another example, the display device 10 may be applied to a wearable display device such as a smart watch, a watch phone, a glasses type display, and a head mounted display (HMD).

The display device 10 according to one example embodiment may be applied to a dashboard of a vehicle, a center fascia of a vehicle, or a center information display (CID) arranged on the dashboard, or may be applied as a room mirror display device replacing a side mirror.

The display device 10 according to one example embodiment may be formed in at least one of a rectangular shape, a square shape, a circular shape, or an oval shape in a plan view. For example, when the display device 10 is used in a vehicle, the display device 10 may be formed in a rectangular shape in which a short side (e.g., a relatively short side) is arranged in a vertical direction and a long side (e.g., a relatively long side) is arranged to be elongated in a horizontal direction. In other words, a side arranged in the vertical direction is shorter than a side arranged to be elongated in the horizontal region. The planar structure of the display device 10 is not limited to the rectangular shape, and the display device 10 may be formed in a rectangular shape in which a long side is positioned in a vertical direction, or may be rotatably installed to variably position the long side in a horizontal or vertical direction.

As shown in FIGS. 1 and 2, the display device 10 includes a touch sensing module, and the touch sensing module includes a touch sensing unit TSU arranged on a front surface of a display panel 100, and at least one touch driving circuit 400 that generates touch coordinate data of the touch sensing unit TSU.

For example, the display panel 100 of the display device 10 includes a display unit DU displaying an image, and the touch sensing unit TSU is arranged on the display unit DU of the display panel 100 to sense a touch of a body portion such as a finger and a touch input device such as an electronic pen.

A plurality of pixels may be included in the display unit DU of the display panel 100, and an image may be displayed through the plurality of pixels. Each pixel may include red, green and blue pixels, or may include red, green, blue and white pixels. In this case, three red, green and blue subpixels may be classified into unit pixels, and four red, green, blue and green subpixels may be classified into unit pixels. In some example embodiments, red, green, blue and white subpixels may be classified into unit pixels.

The display unit DU according to one example embodiment of the present disclosure includes first unit pixels that display an image of a wide viewing angle by implementing the wide viewing angle (or alternatively, a relatively wide viewing angle) and second unit pixels that display an image of a narrow viewing angle (or alternatively, a relatively narrow viewing angle) by implementing the narrow viewing angle. In other words, the first unit pixels are configured to display a first image of a first viewing angle and the second unit pixel display a second image with a second viewing angle which is narrower than the first viewing angle. For example, each of the first unit pixels includes red, green, blue and green subpixels that display an image of the relatively wide viewing angle, and each of the second unit pixels may include red, green, blue and green subpixels that display an image of the relatively narrow viewing angle. As another example, each of the first unit pixels includes red, green, blue and white subpixels that display an image of the relatively wide viewing angle, and each of the second unit pixels may include red, green, blue and white subpixels that display an image of the relatively narrow viewing angle.

For example, because a black matrix BM is not formed between three or four subpixels included in each of the first unit pixels, image display light may be emitted wider in lateral and diagonal directions as well as a front direction. Accordingly, the first unit pixels display an image of a wide viewing angle.

The black matrix BM is formed between three or four subpixels included in each of the second unit pixels, so that image display light is emitted narrower only in the front direction. Because the image display light emitted from the subpixels of each of the second unit pixels in the lateral or diagonal direction is blocked by the black matrix BM, an image may be displayed only by the light emitted in the front direction. Accordingly, luminance and brightness of the image displayed by the subpixels of each of the second unit pixels are deteriorated, and an image of a narrow viewing angle may be displayed through the second unit pixels.

In the present disclosure, a light emission direction control layer made of a low refractive polymer material layer is formed on a front surface of the subpixels included in the first unit pixel, and condensing lenses and a light emission direction control layer made of or including a low refractive polymer material layer covering the condensing lenses are formed on a front surface of the subpixels included in the second unit pixel. Accordingly, the image display light emitted from the subpixels of each of the first unit pixels maintains the same emission direction while passing through the light emission direction control layer made of a low refractive polymer material layer. However, the image display light emitted from the subpixels of each of the second unit pixels is emitted in the front direction by passing through the low refractive polymer material layer in a condensing state in the front direction by the condensing lens. In this way, as the image display light emitted from the subpixels of each of the second unit pixels is emitted in the front direction without being blocked or lost by the black matrix BM, luminance and/or brightness loss of the image display light displayed through the second unit pixels may be reduced. In the present disclosure, a low refractive polymer material layer refers to a thin layer of a polymer that has a refractive index significantly lower than that of many other common optical materials. Typically, the low refractive polymer material layer has refractive indices below 1.5, and often even as low as 1.3 to 1.4.

The touch sensing unit TSU may be packaged in a front direction of the display panel 100, or may be formed integrally with the display panel 100 on the front surface of the display panel 100. The touch sensing unit TSU may include a plurality of touch electrodes and sense a user's touch in a capacitance manner using the touch electrodes. The touch sensing unit TSU may be packaged on the display unit DU of the display panel 100, or may be formed integrally with the display unit DU.

The touch driving circuit 400 may be formed in a type of at least one microprocessor electrically connected to the touch sensing unit TSU (e.g., each touch sensing area). The touch driving circuit 400 may supply touch driving signals to the touch electrodes arranged in the touch sensing unit TSU in a matrix structure and sense the amount of change in capacitance between the touch electrodes. The touch driving circuit 400 may check a user's touch input based on the amount of change in capacitance between the touch electrodes and calculate touch coordinate data. Detailed components and structural features of the touch driving circuit 400 and the touch sensing unit TSU will be described later in more detail with reference to the accompanying drawings.

The display driving circuit 200 may output first control signals and first data voltages for driving the pixels of the display unit DU (e.g., the subpixels included in each of the first unit pixels), and second control signals and second data voltages for driving the subpixels included in each of the second unit pixels.

The display driving circuit 200 may generate and output the first and second control signals and the first and second data voltages when driven in a normal mode, and may generate and output the first control signals and the second data voltages when driven in a privacy mode. In other words, when driven in the normal mode, the display driving circuit 200 controls the image display operation of the first and second unit pixels by driving all of the subpixels of the first and second unit pixels. In addition, when driven in the privacy mode, the display driving circuit 200 may control the image display operation of the second unit pixels by driving the subpixels of only the second unit pixels.

The display driving circuit 200 may supply the first and second data voltages to data lines to which the subpixels of the first and second unit pixels are connected. The display driving circuit 200 may supply a power voltage to a power line, and may supply gate control signals to at least one gate driver 210. The display driving circuit 200 may be separately classified into a timing controller for performing a timing control function, and a data driver for supplying the first and second data voltages to the data lines. In this case, the display driving circuit 200 may control a driving timing of the gate driver 210 and the data driver by supplying a timing control signal to at least one gate driver 210 and data driver.

The display driving circuit 200 may control overall functions of the display device 10. For example, the display driving circuit 200 may receive touch coordinate data for the touch sensing unit TSU from the touch driving circuit 400 to determine a user's touch coordinates and generate digital video data according to the touch coordinates. In addition, the display driving circuit 200 may execute an application indicated by an icon displayed on the user's touch coordinates. As another example, the display driving circuit 200 may receive coordinate data from an electronic pen or the like to determine the touch coordinates of the electronic pen, and then may generate digital video data according to the touch coordinates or execute an application indicated by an icon displayed on the touch coordinates of the electronic pen.

Referring to FIG. 2, the display panel 100 may be classified into a main area MA and a sub-area SBA. The main area MA may include a display area DA in which subpixels for displaying an image are provided, and a non-display area NDA arranged around the display area DA. The display area DA may emit light from a plurality of light emission areas or a plurality of opening areas of the respective subpixels to display an image. To this end, the subpixels arranged in the display area DA may include a pixel circuit including switching elements, a pixel defining layer defining a light emission area or an opening area, and a self-light emitting element.

The non-display area NDA may be a peripheral area, that is, an outer area of the display area DA. The non-display area NDA may be defined as an edge area of the main area MA corresponding to the display area DA of the display panel 100. The non-display area NDA may include at least one gate driver 210 for supplying gate signals to gate lines, and fan-out lines (not shown) for connecting the display driving circuit 200 with the display area DA.

The sub-area SBA may extend from one side of the main area MA. The sub-area SBA may include a flexible material capable of being subjected to bending, folding, rolling, or the like. For example, when the sub-area SBA is bent, the sub-area SBA may overlap the main area MA in a thickness direction (Z-axis direction). The sub-area SBA may include a display driving circuit 200 and a pad portion connected to the circuit board 300. Optionally, the sub-area SBA may be omitted, and the display driving circuit 200 and the pad portion may be arranged in the non-display area NDA.

The circuit board 300 may be attached onto the pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

A substrate SUB of the display panel 100 shown in FIG. 2 may be a base substrate or a base member. The substrate SUB may be a flat type. In some example embodiments, the substrate SUB may be a flexible substrate capable of being subjected to bending, folding, rolling, or the like. For example, the substrate SUB may include a glass material or a metal material, but is not limited thereto. For another example, the substrate SUB may include a polymer resin such as polyimide (PI).

A thin film transistor layer TFTL may be arranged on the substrate SUB. The thin film transistor layer TFTL may include a plurality of thin film transistors constituting a pixel circuit of each of the subpixels. The thin film transistor layer TFTL may further include gate lines, data lines, power lines, gate control lines, fan-out lines connecting the display driving circuit 200 with the data lines, and lead lines connecting the display driving circuit 200 with the pad portion. When the gate driver 210 is formed on each of one side and the other side of the non-display area NDA of the display panel 100, the gate driver 210 may also include thin film transistors.

The thin film transistor layer TFTL may be selectively arranged in the display area DA, the non-display area NDA, and/or the sub-area SBA. Thin film transistors, the gate lines, the data lines, and the power lines of each of the pixels of the thin film transistor layer TFTL may be arranged in the display area DA. The gate control lines and the fan-out lines of the thin film transistor layer TFTL may be arranged in the non-display area NDA. The lead lines of the thin film transistor layer TFTL may be arranged in the sub-area SBA.

A light emitting element layer EML may be arranged on the thin film transistor layer TFTL. The light emitting element layer EML may include a plurality of light emitting elements in which a first electrode, a light emitting layer, and a second electrode are sequentially stacked to emit light, and a pixel defining layer defining each of the pixels. The light emitting elements of the light emitting element layer EML may be arranged in the display area DA.

An encapsulation layer TFEL may cover an upper surface and sides of the light emitting element layer EML, and may protect the light emitting element layer EML. The encapsulation layer TFEL may include at least one inorganic layer and at least one organic layer to encapsulate the light emitting element layer EML.

A light emission direction control layer is formed on a front surface of the encapsulation layer TFEL. In this case, a light emission direction control layer made of or including a low refractive polymer material layer is formed on the front surface of the encapsulation layer TFEL corresponding to the subpixels of the first unit pixel in the front direction.

On the other hand, condensing lenses and a light emission direction control layer made of (or including) a low refractive polymer material layer and covering the condensing lens are formed on the front surface of the encapsulation layer TFEL corresponding to the subpixels of the second unit pixel in the front direction.

The touch sensing unit TSU including the touch sensing area may be arranged on the light emission direction control layer of the display panel 100. The touch sensing area of the touch sensing unit TSU may include a plurality of touch electrodes for sensing a user's touch in a capacitance manner, and touch driving lines for connecting the plurality of touch electrodes with at least one touch driving circuit 400. The touch electrodes are arranged in each touch sensing area in a matrix structure to sense a user's touch in a self-capacitance manner or a mutual capacitance manner.

The touch sensing unit TSU may not be integrally formed on the display panel 100, but be arranged on a separate substrate or film arranged on the display unit DU of the display panel 100. In this case, the substrate or film supporting the touch sensing unit TSU may be a base member for encapsulating the display unit DU. Hereinafter, an example in which the touch sensing unit TSU is integrally formed on the front surface of the display unit DU will be described.

The plurality of touch electrodes may be arranged in the touch sensing area that overlaps the display area DA. On the other hand, the touch lines that transmit touch driving signals or touch sensing signals may be arranged in a touch peripheral area that overlaps the non-display area NDA.

The touch driving circuit 400 for generating touch coordinate data for the touch sensing area may be arranged in the non-display area NDA or the sub-area SBA of the display panel 100. In some example embodiments, the touch driving circuit 400 for generating touch coordinate data may be packaged on a separate circuit board 300. The touch driving circuit 400 may be formed as an integrated circuit (IC).

The touch driving circuit 400 supplies the touch driving signals to the touch electrodes of the touch sensing area that overlaps the display area DA, and measures the amount of change in charges of mutual capacitance of each of a plurality of touch nodes formed by the touch electrodes. In this case, the touch driving circuit 400 measures a change in capacitance of the touch nodes in accordance with a voltage magnitude or the amount of change in a current of the touch sensing signal received through the touch electrodes. In this way, the touch driving circuit 400 may determine a user's touch position depending on the amount of change in charges of mutual capacitance of each of the touch nodes. The touch driving signal may be a pulse signal having a frequency. The touch driving circuit 400 calculates whether there is a touch input of a touch input device or a user's body portion such as a finger for each touch sensing area and touch coordinates based on the amount of change in capacitance between the touch electrodes for each touch sensing area.

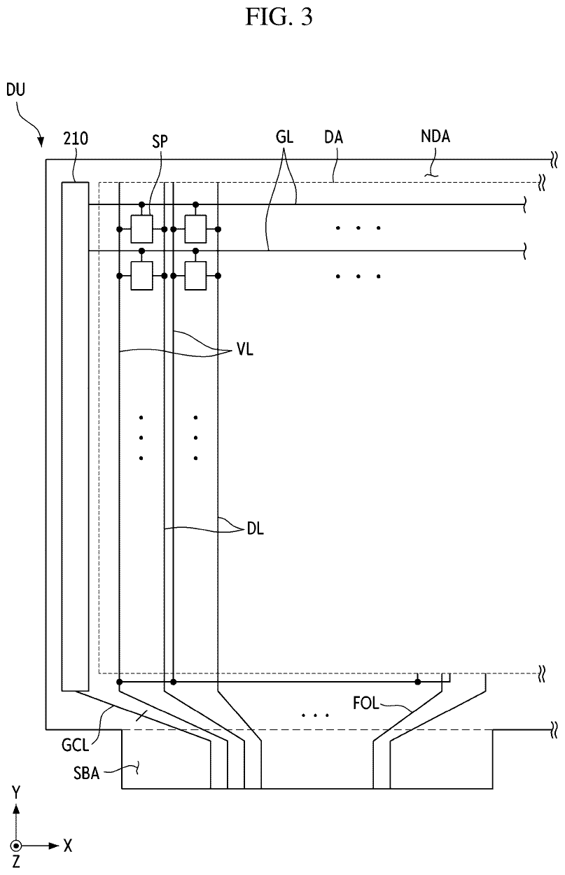

FIG. 3 is a schematic layout view illustrating an example of a display panel according to one example embodiment. For example, FIG. 3 is a layout view partially illustrating the display area DA and the non-display area NDA of the display unit DU that is in a state before the touch sensing unit TSU is formed.

The display area is an area for displaying an image, and may be defined as a central area of the display panel 100. For example, the display area DA may include a plurality of subpixels SP, a plurality of gate lines GL, a plurality of data lines DL, and a plurality of power lines VL. Each of the plurality of subpixels SP may be defined as a minimum unit (or alternatively, a basic unit) that outputs light of red, green, blue, or white.

The plurality of gate lines GL may supply the gate signals received from at least one gate driver 210 to the plurality of subpixels SP. The plurality of gate lines GL may extend in X-axis direction, and may be spaced apart from each other in Y-axis direction crossing the X-axis direction.

The plurality of data lines DL may supply the data voltages received from the display driving circuit 200 to the plurality of subpixels SP. The plurality of data lines DL may extend in the Y-axis direction, and may be spaced apart from each other in the X-axis direction.

The plurality of power lines VL may supply a power voltage applied from the display driving circuit 200 or a separate power supply unit to the plurality of subpixel SP. The power voltage may be at least one of a driving voltage, an initialization voltage, or a reference voltage. The plurality of power lines VL may extend in the Y-axis direction, and may be spaced apart from each other in the X-axis direction.

The non-display area NDA is a peripheral area of the display area DA that surrounds the display area DA1 in which an image is displayed, and may be finally defined as a bezel area. The non-display area NDA may include a gate driver 210, fan-out lines FOL, and gate control lines GCL. The gate driver 210 may generate a plurality of gate signals based on the gate control signal, and may sequentially supply the plurality of gate signals to the plurality of gate lines GL in accordance with a set order.

The fan-out lines FOL may extend from the display driving circuit 200 to each display area DA. The fan-out lines FOL may supply the data voltage received from the display driving circuit 200 to the plurality of data lines DL.

The gate control line GCL may extend from the display driving circuit 200 to the gate driver 210. The gate control line GCL may supply the gate control signal received from the display driving circuit 200 to the gate driver 210.

The display driving circuit 200 may output first and second control signals and driving voltages for driving the display panel 100 to the fan-out lines FOL. The display driving circuit 200 may supply the first and second data voltages to the data line DL through the fan-out lines FOL. The first and second data voltages may be supplied to the plurality of subpixels SP, and may determine luminance of the plurality of subpixels SP. The display driving circuit 200 may supply the gate control signal to the gate driver 210 through the gate control line GCL.

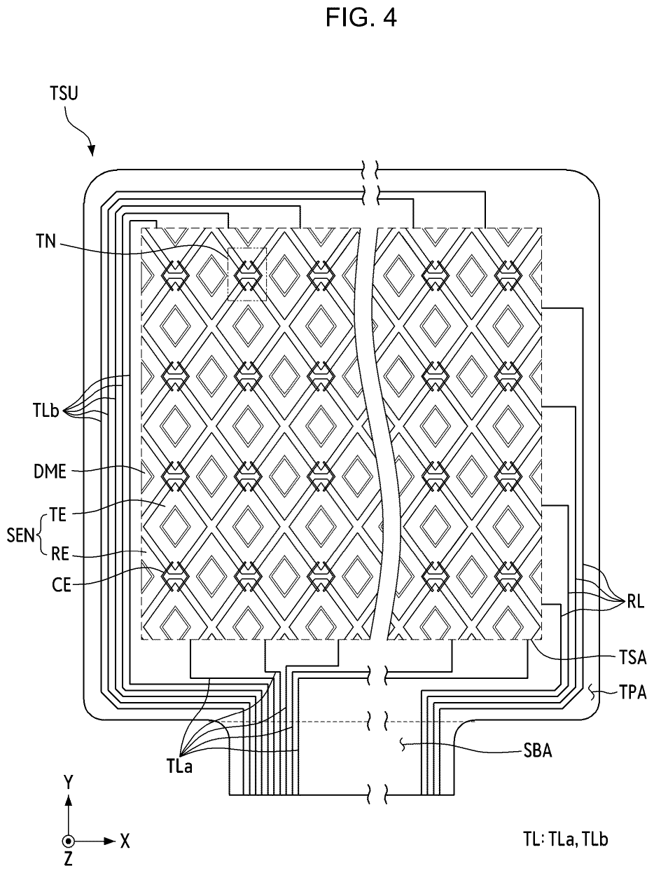

FIG. 4 is a schematic layout view illustrating an example of a touch sensing unit according to one example embodiment. For example, FIG. 4 is a layout view illustrating a planar structure of the touch sensing area TSA corresponding to the display area DA.

Referring to FIG. 4, the touch sensing unit TSU may include a touch sensing area TSA for sensing a user's touch, and a touch peripheral area TPA defined as a peripheral area of the touch sensing area TSA.

The touch sensing area TSA may overlap the display area DA and the non-display area NDA by covering the display area DA of the display unit DU. Because the non-display area NDA is a bezel area, outer areas of the touch sensing area TSA, which overlaps and corresponds to the non-display area NDA, correspond to the bezel area.

The touch peripheral area TPA corresponds to an arrangement area of the gate driver 210. Accordingly, the touch sensing area TSA extends and is arranged on the non-display area NDA excluding the arrangement area of the gate driver 210, to overlap the non-display area NDA.

The touch sensing area TSA may include a plurality of touch electrodes SEN and a plurality of dummy electrodes DME. The plurality of touch electrodes SEN may form mutual capacitance or self-capacitance to sense an object or a person's touch. The plurality of touch electrodes SEN may include a plurality of driving electrodes TE and a plurality of sensing electrodes RE.

The plurality of driving electrodes TE may be arranged in the X-axis direction and the Y-axis direction. The plurality of driving electrodes TE may be spaced apart from each other in the X-axis direction and the Y-axis direction. The driving electrodes TE adjacent to each other in the Y-axis direction may be electrically connected to each other through a plurality of connection electrodes CE.

The plurality of driving electrodes TE may be connected to first touch pads through the driving line TL. The driving line TL may include a lower driving line TLa and an upper driving line TLb. For example, some of the driving electrodes TE arranged below the touch sensing area TSA may be connected to the first touch pads through the lower driving line Tla, and other some of the driving electrodes TE arranged above the touch sensing area TSA may be connected to the first touch pads through the upper driving line TLb. The lower driving line Tla may extend to the first touch pads by passing through a lower side of the touch peripheral area TPA. The upper driving line TLb may extend to the first touch pads by passing through an upper side, a left side, and the lower side of the touch peripheral area TPA. In this case, the touch pads that are not denoted may be pads formed on the circuit board 300 or the like and connected to at least one touch driving circuit 400.

The driving electrodes TE adjacent to each other in the Y-axis direction may be electrically connected to each other by the plurality of connection electrodes CE. Thus, even though any one of the plurality of connection electrodes CE is disconnected, the driving electrodes TE may be stably connected to each other through the other connection electrodes CE. The driving electrodes TE adjacent to each other may be connected by two connection electrodes CE, but the number of connection electrodes CE is not limited thereto. The connection electrode CE may be bent at least once. For example, the connection electrode CE may have a bent shape (“<” or “>”), but its planar shape is not limited thereto.

The connection electrode CE may be arranged on a different layer from the plurality of driving electrodes TE and the plurality of sensing electrodes RE. The driving electrodes TE adjacent to each other in the Y-axis direction may be electrically connected to each other through the connection electrode CE arranged on the different layer from the plurality of driving electrodes TE or the plurality of sensing electrodes RE. The connection electrodes CE may be formed on a rear layer (or a lower layer) of a layer on which the driving electrodes TE and the sensing electrodes RE are formed. Each of the connection electrodes CE are electrically connected to corresponding ones of the driving electrodes TE adjacent thereto through corresponding ones of a plurality of contact holes. Accordingly, even though the connection electrodes CE overlap the plurality of sensing electrodes RE in Z-axis direction, the plurality of driving electrodes TE may be insulated from the plurality of sensing electrodes RE. The mutual capacitance may be formed between the driving electrode TE and the sensing electrode RE.

The sensing electrodes RE adjacent to each other in the X-axis direction may be electrically connected to each other through a connection portion arranged on the same layer as the plurality of driving electrodes TE or the plurality of sensing electrodes RE. That is, the plurality of sensing electrodes RE may extend in the X-axis direction, and may be spaced apart from each other in the Y-axis direction. The plurality of sensing electrodes RE may be arranged in the X-axis direction and the Y-axis direction, and the sensing electrodes RE adjacent to each other in the X-axis direction may be electrically connected to each other through the connection portion.

Touch nodes TN are formed in areas where the connection electrodes CE connecting the driving electrodes TE cross the connection portion of the sensing electrodes RE, so that the touch nodes TN may be arranged in the touch sensing area TSA in a matrix form.

The plurality of sensing electrodes RE may be connected to second touch pads through sensing lines RL. For example, some of the sensing electrodes RE, which are arranged on a right side of the touch sensing area TSA, may be connected to the second touch pads through the sensing lines RL. The sensing lines RL may extend to the second touch pads by passing through the right and lower sides of the touch peripheral area TPA. The second touch pads may be connected to at least one touch driving circuit 400 through the circuit board 300.

Each of the plurality of dummy electrodes DME may be surrounded by the driving electrode TE or the sensing electrode RE. Each of the plurality of dummy electrodes DME may be insulated from the driving electrode TE or the sensing electrode RE by being spaced apart from the driving electrode TE or the sensing electrode RE. Thus, the dummy electrode DME may be electrically floated.

The touch driving circuit 400 supplies the touch driving signal to the plurality of driving electrodes TE. In addition, the touch driving circuit 400 receives a signal fed back from each of the plurality of driving electrodes TE as a touch sensing signal of the driving electrodes TE, and receives a touch sensing signal for the sensing electrodes RE from each of the plurality of sensing electrodes RE. Accordingly, the touch driving circuit 400 measures a change in the magnitude of the touch sensing signal received from the plurality of driving electrodes TE and the plurality of sensing electrodes RE, and thus measures the amount of change in charges of mutual capacitance of each of the touch nodes TN formed by the plurality of driving electrodes TE and the plurality of sensing electrodes RE. The touch driving circuit 400 may determine the user's touch position and touch moving direction depending on the amount of change in charges of mutual capacitance of each of the touch nodes. In this way, the touch driving circuit 400 calculates whether there is a touch input of a touch input device or a user's body portion such as a finger for each touch sensing area and touch coordinates based on the amount of change in capacitance between the touch electrodes.

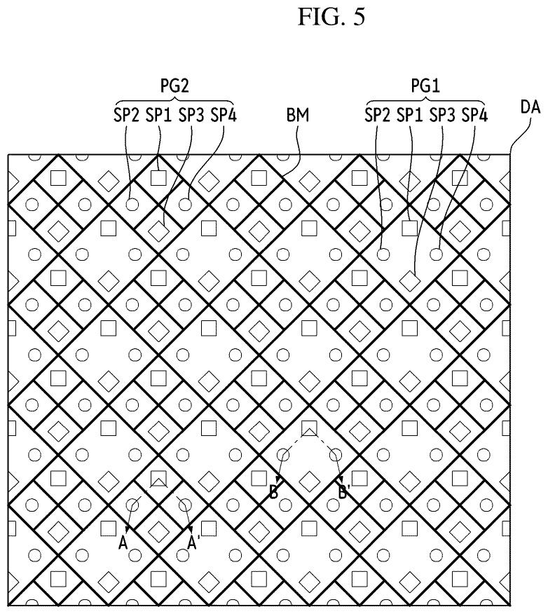

FIG. 5 is a plan view partially illustrating a subpixel arrangement structure of a display area, according to one example embodiment.

Referring to FIG. 5, in the display area DA of the display panel 100, first unit pixels PG1 for displaying an image of a wide viewing angle (or alternatively, a relatively wide viewing angle) by implementing the wide viewing angle and second unit pixels PG2 for displaying an image of a narrow viewing angle by implementing the narrow viewing angle may be arranged in a pentile matrix structure. Accordingly, first to fourth subpixels SP1, SP2, SP3 and SP4 included in the first and second unit pixels PG1 and PG2 may be also arranged in a pentile matrix structure.

For example, each of the first and second unit pixels PG1 and PG2 may include first to fourth subpixels SP1, SP2, SP3 and SP4 arranged in a pentile matrix structure. The plurality of first to fourth subpixels SP1, SP2, SP3 and SP4 may be provided by intersection between ‘n’ data lines (where ‘n’ is a natural number) and ‘m’ scan lines (where ‘m’ is a natural number equal to or different from ‘n’).

For example, among the first to fourth subpixels SP1, SP2, SP3 and SP4 included in each of the first and second unit pixels PG1 and PG2, the first subpixel SP1 may be a red subpixel, the second and fourth subpixels SP2 and SP4 may be the same green subpixels, and the third subpixel SP3 may be a blue subpixel.

A size of an opening area of each of the first to fourth subpixels SP1, SP2, SP3 and SP4 may be determined depending on luminance of corresponding light. Accordingly, the size of the opening area of each of the first to fourth subpixels SP1, SP2, SP3 and SP4 may be adjusted to implement white light by mixing light emitted from each of a plurality of light emitting layers. Each of the first to fourth subpixels SP1, SP2, SP3 and SP4 included in the first unit pixels PG1 outputs light having luminance and brightness corresponding to magnitudes of the first data voltages supplied from the display driving circuit 200. In addition, each of the first to fourth subpixels SP1, SP2, SP3 and SP4 included in the second unit pixels PG2 outputs light having luminance and brightness corresponding to magnitudes of the second data voltages supplied from the display driving circuit 200.

As described above, the black matrix BM is not formed in areas between the first to fourth subpixels SP1, SP2, SP3 and SP4 included in each of the first unit pixels PG1. Accordingly, image display light displayed in the first to fourth subpixels SP1, SP2, SP3 and SP4 of the first unit pixel PG1 may be more widely emitted in lateral and diagonal directions in addition to the front direction. On the other hand, the black matrix BM is formed and arranged between the first to fourth subpixels SP1, SP2, SP3 and SP4 included in each of the second unit pixels PG2. Accordingly, image display light displayed in the first to fourth subpixels SP1, SP2, SP3 and SP4 of the second unit pixel PG2 is narrowly emitted only in the front direction of the first to fourth subpixels SP1, SP2, SP3 and SP4 through an opening area of the black matrix BM. That is, because the image display light emitted from the first to fourth subpixels SP1, SP2, SP3 and SP4 of the second unit pixel PG2 is blocked by the black matrix BM, an image may be displayed only by the light emitted in the front direction.

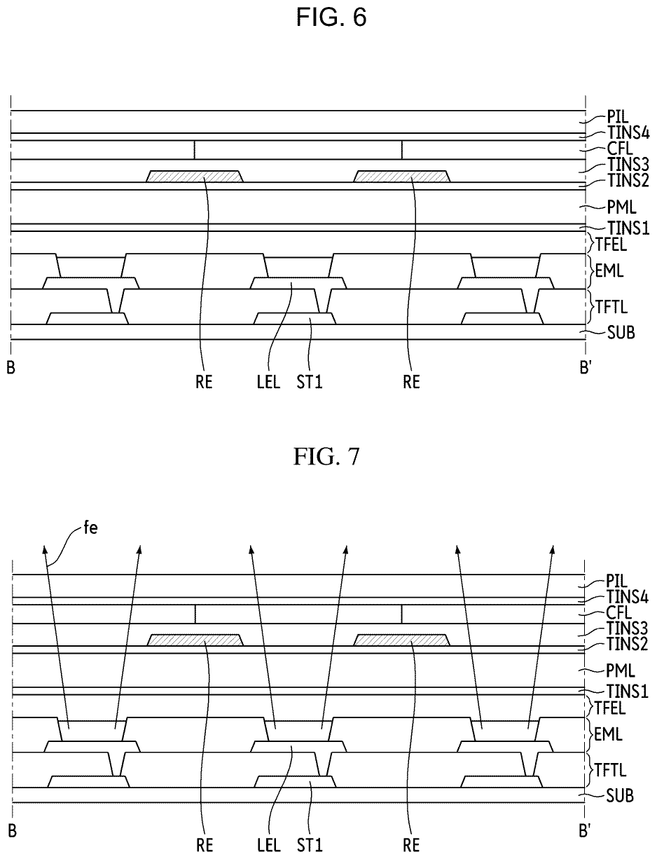

FIG. 6 is a brief cross-sectional view illustrating a cross-sectional structure of line B-B′ of FIG. 5, according to one example embodiment.

For example, FIG. 6 shows a cross-sectional structure in which a light emission direction control layer PML made of or including a low refractive polymer material is included and arranged in the first to fourth subpixels SP1, SP2, SP3 and SP4 included in the first unit pixel PG1. In other words, a portion of the light emission direction control layer PML arranged in a front direction of the subpixels (e.g., the first to fourth subpixels SP1, SP2, SP3 and SP4) for each first unit pixel (in the first unit pixel PG) includes only a low refractive polymer material layer.

Referring to FIG. 6, a barrier layer and the thin film transistor layer TFTL including the barrier layer are formed on the substrate SUB. The barrier layer is a film for protecting thin film transistors ST1 of the thin film transistor layer TFTL and light emitting elements LEL of the light emitting element layer EML that is vulnerable to moisture permeation from moisture permeated through the substrate SUB.

The thin film transistor layer TFTL may further include gate lines, data lines, power lines, gate control lines, fan-out lines connecting the display driving circuit 200 with the data lines, and lead lines connecting the display driving circuit 200 with the pad portion.

The thin film transistors ST1 of the thin film transistor layer TFTL may include an active layer, a gate electrode, a source electrode, and a drain electrode.

An anode connection electrode is electrically connected to the drain electrode of the thin film transistors ST1. The anode connection electrode may be connected to the drain electrode of the thin film transistor ST1 through a contact hole passing through at least one interlayer insulating layer.

The light emitting element layer EML, that is, the light emitting elements LEL and banks, may be arranged on a front surface of the thin film transistor layer TFTL in which anode connection electrodes are electrically connected to each subpixel area. The light emitting elements LEL formed in each subpixel area include a pixel electrode, a light emitting layer, and a common electrode. Banks defining the light emitting layer are arranged in areas between the respective subpixel areas.

The encapsulation layer TFEL is formed by covering an upper surface and sides of the light emitting device layer EML to protect the light emitting element layer EML. The encapsulation layer TFEL may include at least one inorganic layer and at least one organic layer to encapsulate the light emitting element layer EML.

A first inorganic insulating layer TINS1 for enhancing planarization and insulation characteristics may be further formed on a front surface of the encapsulation layer TFEL. The first inorganic insulating layer TINS1 may include a silicon nitride layer, a silicon oxynitride layer, a silicon oxide layer, a titanium oxide layer, or an aluminum oxide layer.

A light emission direction control layer PML made of or including a low refractive polymer material layer is formed on the front surface of the encapsulation layer TFEL including the first inorganic insulating layer TINS1, for example, on the front surface of the encapsulation layer TFEL corresponding to the first to fourth subpixels SP1, SP2, SP3 and SP4 of the first unit pixel PG1 in the front direction. Accordingly, the image display light emitted from the first to fourth subpixels SP1, SP2, SP3 and SP4 of the first unit pixel PG1 may remain the same emission direction while passing through the light emission direction control layer PML made of or including a low refractive polymer material layer.

A second inorganic insulating layer TINS2 for enhancing planarization and insulation characteristics may be further formed on the front surface of the light emission direction control layer PML. The second inorganic insulating layer TINS2 may include a silicon nitride layer, a silicon oxynitride layer, a silicon oxide layer, a titanium oxide layer, or an aluminum oxide layer.

Touch electrodes SEN of at least one of the driving electrodes TE, the sensing electrodes RE or the dummy electrodes DEM may be arranged on the second inorganic insulating layer TINS2. For example, the sensing electrodes RE of the touch electrodes SEN may be arranged on the second inorganic insulating layer TINS2. The sensing electrodes RE may include any one of molybdenum (Mo), aluminum (Al), chromium (Cr), gold (Au), titanium (Ti), nickel (Ni), neodymium (Nd) and copper (Cu), or their alloy. The driving electrodes TE and the sensing electrodes RE may be formed in a mesh structure or a net structure so as not to overlap the subpixel areas.

A third inorganic insulating layer TINS3 is formed on the second inorganic insulating layer TINS2 including the driving electrodes TE and the sensing electrodes RE. The third inorganic insulating layer TINS3 may include an inorganic layer, that is, a silicon nitride layer, a silicon oxynitride layer, a silicon oxide layer, a titanium oxide layer, or an aluminum oxide layer. In some example embodiments, the third touch insulating layer TINS3 may include an organic layer such as an acrylic resin, an epoxy resin, a phenolic resin, a polyamide resin, or a polyimide resin.

A plurality of color filter layers CFL may be formed on the third inorganic insulating layer TINS3. For example, the color filter layer CFL including red, blue and green color filters may be arranged on the third inorganic insulating layer TINS3 in a planar shape.

A fourth inorganic insulating layer TINS4 for protecting the plurality of color filter layers CFL may be formed on the color filter layer CFL, and a shielding layer PIL for covering and shielding both the color filter layer CFL and the fourth inorganic insulating layer TINS4 may be further formed on the fourth inorganic insulating layer TINS4.

FIG. 7 is a cross-sectional view illustrating an emission direction of image display light emitted from first to fourth subpixels included in a first unit pixel of FIG. 6 by arrows.

As shown in FIGS. 6 and 7, the image display light emitted from the subpixels SP1, SP2, SP3 and SP4 of each of the first unit pixels PG1 maintains the same emission direction while passing through the light emission direction control layer PML made of or including a low refractive polymer material layer.

In addition, because the black matrix BM is not formed in areas between the first to fourth subpixels SP1, SP2, SP3 and SP4 included in each of the first unit pixels PG1, the image display light passing through the light emission direction control layer PML also maintains the same emission direction in a direction of an arrow fe. Accordingly, the image display light displayed in the first to fourth subpixels SP1, SP2, SP3 and SP4 of the first unit pixel PG1 may be emitted more widely in the lateral and diagonal directions in addition to the front direction through the light emission direction control layer PML.

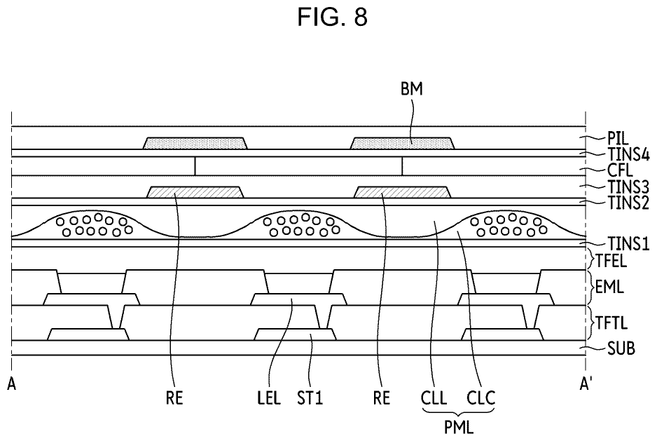

FIG. 8 is a brief cross-sectional view illustrating a cross-sectional structure of line A-A′ of FIG. 5 according to the first embodiment.

For example, FIG. 8 shows a cross-sectional structure in which a light emission direction control layer PML made of or including condensing lenses CLC and a low refractive polymer material layer CLL covering the condensing lenses CLC is arranged in the first to fourth subpixels SP1, SP2, SP3 and SP4 included in the second unit pixel PG2. In other words, a portion of the light emission direction control layer PML arranged in a front direction of the subpixels (e.g., the first to fourth subpixels SP1, SP2, SP3 and SP4) for each second unit pixel (in the first unit pixel PG) includes both the condensing lenses CLC and the low refractive polymer material layer covering the condensing lenses CLL.

Referring to FIG. 8, a thin film transistor layer TFTL including a barrier layer is formed on the substrate SUB, and a light emitting element layer EML including light emitting elements LEL and banks is formed and arranged on the thin film transistor layer TFTL. An encapsulation layer TFEL is formed to cover the upper surface and sides of the light emitting element layer EML. Also, a first inorganic insulating layer TINS1 for enhancing planarization and insulation characteristics may be further formed on the front surface of the encapsulation layer TFEL.

A light emission direction control layer PML made of or including condensing lenses CCL and a low refractive polymer material layer CLL covering the condensing lenses CLC is formed on the front surface of the encapsulation layer TFEL (e.g., on the front surface of the first inorganic insulating layer TINS1), for example, on the front surface of the encapsulation layer TFEL corresponding to the first to fourth subpixels SP1, SP2, SP3 and SP4 of the second unit pixel PG2 in the front direction.

The condensing lenses CLC are formed and arranged at positions corresponding to the first to fourth subpixels SP1, SP2, SP3 and SP4 of the second unit pixel PG2 in the front direction.

The condensing lenses CLC are formed as lenses having a hemispherical cross-sectional shape, or a polygonal cross-sectional shape such as a triangle, a square, or a rhombus, and condenses image display light incident in a direction of a flat rear surface to pass through the light in a direction of a convex front surface. The condensing lenses CLC may be formed to include birefringent members, such as liquid crystals, therein.

The low refractive polymer material layer CLL is formed to fully cover the front surface of the first inorganic insulating layer TINS1, including the condensing lenses CLC and the encapsulation layer TFEL.

The low refractive polymer material layer CLL maintains the image display light condensed by the condensing lenses CLC in the front direction of the condensing lenses CLC, which is a direction in which the image display light is condensed without being scattered in the lateral or diagonal direction.

A second inorganic insulating layer TINS2 for enhancing planarization and insulation characteristics may be further formed on the front surface of the light emission direction control layer PML made of or including the condensing lenses CLC and the low refractive polymer material layer CLL.

Touch electrodes SEN of at least one of the driving electrodes TE, the sensing electrodes RE or the dummy electrodes DEM are arranged on the second inorganic insulating layer TINS2, and a third inorganic insulating layer TINS3 is formed on the second inorganic insulating layer TINS2 including the driving electrodes TE and the sensing electrodes RE.

A plurality of color filter layers CFL may be formed on the third inorganic insulating layer TINS3, and a fourth inorganic insulating layer TINS4 for protecting the plurality of color filter layers CFL may be formed on the color filter layer CFL.

A black matrix BM is formed and arranged in a partial front area of the fourth inorganic insulating layer TINS4, at positions corresponding to a peripheral area of each of the second unit pixels PG2 (e.g., each second unit pixel PG2) and areas between the first to fourth subpixels SP1, SP2, SP3 and SP4 classified into the second unit pixels PG2, in a mesh structure. That is, the black matrix BM is formed in areas, which correspond to a peripheral area (or outer area) of each of the second unit pixels PG2 (e.g., each second unit pixel PG2) and areas between the first to fourth subpixels SP1, SP2, SP3 and SP4 included in the second unit pixels PG2, in a mesh structure. Referring to FIG. 5, the black matrix BM is also arranged at an area, which correspond to a peripheral area (or outer area) of each of the first unit pixels PG1 (e.g., each first unit pixel PG1), in a mesh structure and is not arranged at areas between the first to fourth subpixels SP1, SP2, SP3 and SP4 included in each of the first unit pixels PG1. Accordingly, image display light displayed in the first to fourth subpixels SP1, SP2, SP3 and SP4 of the second unit pixels PG2 may be condensed by the condensing lenses CLC and the low refractive polymer material layer CLL, and may be narrowly emitted in a front direction of the condensing lenses CLC through the opening area of the black matrix BM. In this way, the image display light emitted from the first to fourth subpixels SP1, SP2, SP3 and SP4 of the second unit pixel PG2 is emitted in the front direction without being blocked or lost by the black matrix BM, thereby reducing luminance and brightness loss of the image display light displayed through the second unit pixels PG2.

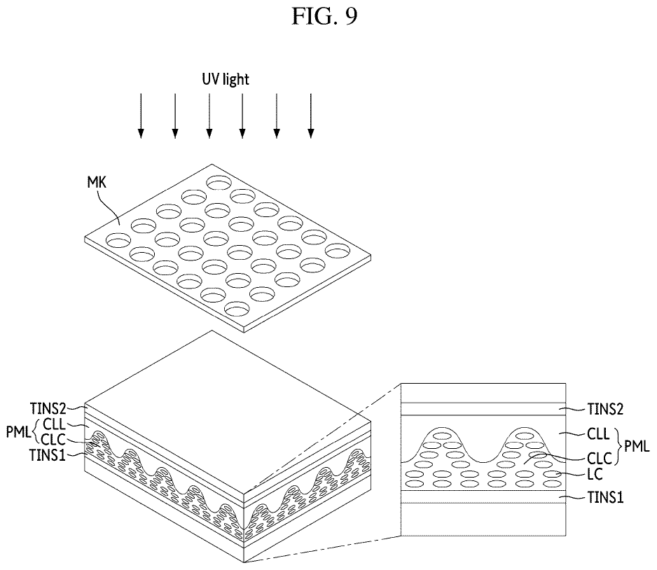

FIG. 9 is a view illustrating a method of forming condensing lenses and a low refractive polymer material layer of a light emission direction control layer shown in FIG. 8.

Referring to FIG. 9, when the light emission direction control layer PML is formed, a polymer material layer including birefringent members LC such as liquid crystals is coated or printed on the front surface of the encapsulation layer TFEL or on the front surface of the first inorganic insulating layer TINS1. In addition, a low refractive polymer material layer CLL made of or including a low refractive polymer is additionally coated and printed on a front surface of the polymer material layer including the birefringent members LC.

In a state that the low refractive polymer material layer CLL is formed on the front surface of the polymer material layer including birefringent members LC to overlap the polymer material layer, a mask MK having openings formed at positions corresponding to the first to fourth subpixels SP1, SP2, SP3 and SP4 of the second unit pixel PG2, respectively, is arranged in a front direction of the low refractive polymer material layer CLL. Then, ultraviolet light of a desired or preset wavelength band is applied to a front surface of the mask MK for a desired or preset period of time. Accordingly, at a position corresponding to the opening, that is, at the positions corresponding to the first to fourth subpixels SP1, SP2, SP3 and SP4 of the second unit pixel PG2, the birefringent members LC and a polymer material layer including the birefringent members LC are concentrated in a convex shape. The low refractive polymer material layer CLL is maintained in a planarized state. Afterwards, in the process of curing the polymer material layer including the birefringent members LC and the low refractive polymer material layer CLL, condensing lenses CLC are formed inside the low refractive polymer material layer CLL.

When the opening of the mask MK is formed in a semi-transmissive state by a slit or filter structure, the polymer material layer including the birefringent members LC may have a convex cross-section in a polygonal shape such as a triangle, a rhombus, or a square when transmitted by ultraviolet rays.

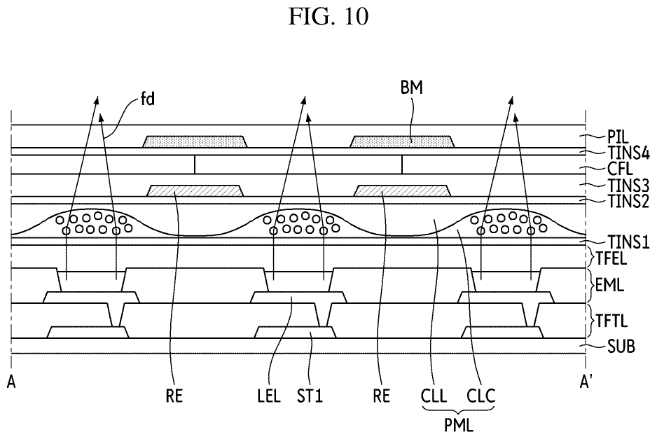

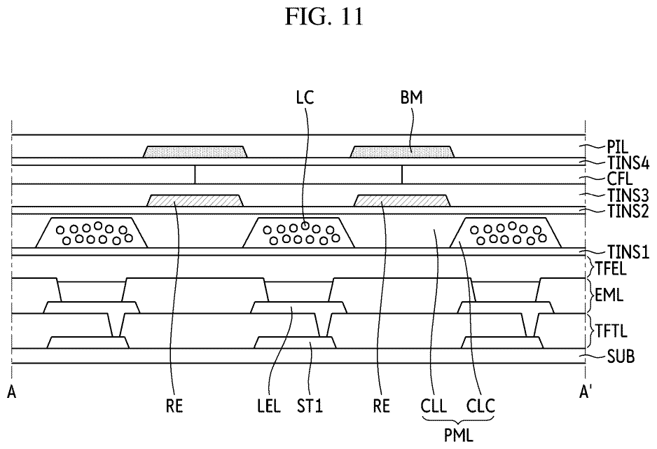

FIG. 10 is a cross-sectional view illustrating an emission direction of image display light emitted from first to fourth subpixels included in a second unit pixel of FIG. 8 by arrows.

As shown in FIG. 10, image display light displayed in the first to fourth subpixels SP1, SP2, SP3 and SP4 of the second unit pixel PG2 may be condensed by the condensing lenses CLC, and may be narrowly emitted in a front direction of the condensing lenses CLC through the low refractive polymer material layer CLL and the opening area of the black matrix BM.

In other words, as indicated by an arrow (e.g., an arrow fd), the image display light displayed in the first to fourth subpixels SP1, SP2, SP3 and SP4 of the second unit pixel PG2 may be narrowly emitted only in the front direction of the first to fourth subpixels SP1, SP2, SP3 and SP4 through the opening area of the black matrix BM.

In this way, the image display light emitted from the first to fourth subpixels SP1, SP2, SP3 and SP4 of the second unit pixel PG2 is emitted in the front direction without being blocked or lost by the black matrix BM, thereby reducing luminance and brightness loss of the image display light displayed through the second unit pixels PG2.

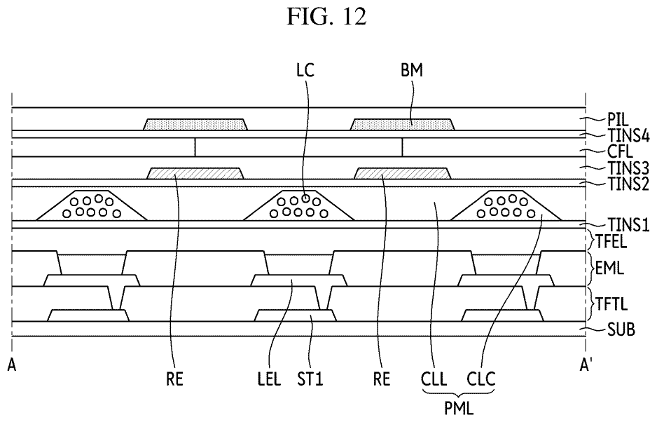

FIG. 11 is a brief cross-sectional view illustrating a cross-sectional structure of line A-A′ of FIG. 5 according to the second example embodiment. FIG. 12 is a brief cross-sectional view illustrating a cross-sectional structure of line A-A′ of FIG. 5 according to the third example embodiment.

Referring to FIGS. 11 and 12, the condensing lenses CLC are formed at positions corresponding to the first to fourth subpixels SP1, SP2, SP3 and SP4 of the second unit pixel PG2 in the front direction, and their cross-sectional shapes may be formed in a polygonal shape such as a triangle, a square, a trapezoid, and a rhombus in addition to a hemispherical shape.

For example, in the process of forming the condensing lenses CLC using the mask MK and ultraviolet light, the opening of the mask MK is formed in a semi-transmissive slit or filter structure, so that the birefringent members LC and the polymer material layer including and the birefringent members LC may be concentrated in a polygonal shape such as a triangle, a square, a trapezoid, and a rhombus. The polymer material layer including the birefringent members LC and the low refractive polymer material layer CLL may be cured so that the condensing lenses CLC may be formed inside the low refractive polymer material layer CLL.

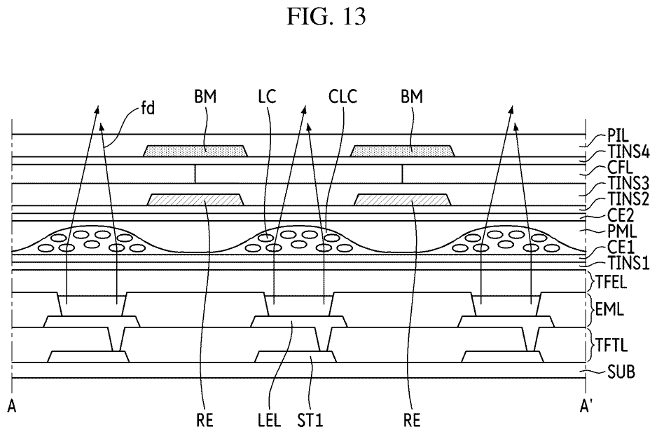

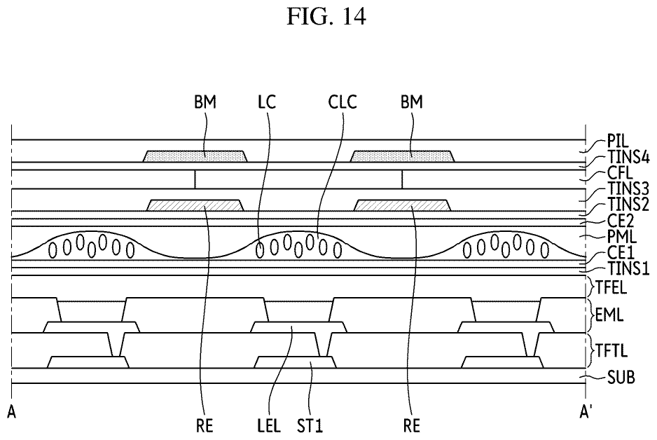

FIG. 13 is a brief cross-sectional view illustrating a cross-sectional structure of line A-A′ of FIG. 5 according to the fourth example embodiment. FIG. 14 is a brief cross-sectional view illustrating a cross-sectional structure of line A-A′ of FIG. 5 according to the fifth example embodiment.

Referring to FIGS. 13 and 14, a first common electrode CE1 may be formed on the front surface of the encapsulation layer TFEL or the front surface of the first inorganic insulating layer TINS1. The first common electrode CE1 may include a transparent conductive material (TCO) such as ITO or IZO, which is capable of transmitting light, or a desired or preset semi-transmissive conductive material such as magnesium (Mg), silver (Ag), or an alloy of magnesium (Mg) and silver (Ag). When the first common electrode CE1 includes a semi-transmissive conductive material, light emission efficiency may be enhanced by a micro cavity.

Afterwards, a light emission direction control layer PML is formed on the first common electrode CE1. For example, a light emission direction control layer PML made of or including condensing lenses CLC and a low refractive polymer material layer CLL covering the condensing lenses CLC is formed on a front surface of the first common electrode CE1 corresponding to the first to fourth subpixels SP1, SP2, SP3 and SP4 of the second unit pixel PG2 in the front direction.

Due to an arrangement structure of the opening of the mask MK, the condensing lenses CLC are formed and arranged only at the positions corresponding to the first to fourth subpixels SP1, SP2, SP3 and SP4 of the second unit pixel PG2 in the front direction, respectively.

The condensing lenses CLC are formed as lenses having a hemispherical cross-sectional shape, or a polygonal cross-sectional shape such as a triangle, a square, a trapezoid, or a rhombus, and condenses image display light incident in a direction of a flat rear surface to pass through the light in a direction of a convex front surface. The condensing lenses CLC may be formed to include birefringent members, such as liquid crystals, therein.

Next, a second common electrode CE2 is formed on the front surface of the light emission direction control layer PML. The second common electrode CE2 may include the same metal material as that of the first common electrode CE1.

A second inorganic insulating layer TINS2 for enhancing planarization and insulation characteristics may be formed on a front surface of the second common electrode CE2, and touch electrodes SEN of at least one of the driving electrodes TE, the sensing electrodes RE or the dummy electrodes DEM may be arranged on the second inorganic insulating layer TINS2.

A third inorganic insulating layer TINS3 may be formed on the second inorganic insulating layer TINS2. A plurality of color filter layers CFL may be formed on the third inorganic insulating layer TINS3, and a fourth inorganic insulating layer TINS4 for protecting the color filter layers CFL may be formed on the color filter layers CFL.

A black matrix BM is formed and arranged in a partial front area of the fourth inorganic insulating layer TINS4, which corresponds to a peripheral area of and areas between the first to fourth subpixels SP1, SP2, SP3 and SP4 classified into the second unit pixels PG2, in a mesh structure.

Referring to FIG. 13, when driven in a privacy mode, the display driving circuit 200 may control the image display operation of the second unit pixels PG2 by driving only the first to fourth subpixels SP1, SP2, SP3 and SP4 of the second unit pixels PG2.

When driven in the privacy mode, the display driving circuit 200 may supply driving voltages of different magnitudes to the first common electrode CE1 and the second common electrode CE2, so that the birefringent members LC such as liquid crystals arranged inside the condensing lenses CLC may vary their arrangement by a potential difference due to the driving voltages of the different magnitudes.

For example, when driven in the privacy mode, the display driving circuit 200 may supply a high potential driving voltage of about 15V or more to the first common electrode CE1 and a low potential driving voltage of less than 5V to the second common electrode CE2. In this case, the birefringent members LC such as liquid crystals arranged inside the condensing lenses CLC may vary their arrangement by a potential difference between the relatively high potential driving voltage and the relatively low potential driving voltage. In this case, the condensing lenses CLC may condense image display light incident from a rear direction thereof and pass through the light in a front direction.

On the other hand, referring to FIG. 14, when driven in a normal mode, the display driving circuit 200 may control the image display operation of the first and second unit pixels PG1 and PG2 by driving both the first and second unit pixels PG1 and PG2.

When driven in the normal mode, the display driving circuit 200 may supply driving voltages having the same magnitude, such as 0V or 5V, to the first common electrode CE1 and the second common electrode CE2, respectively. In some example embodiments, the display driving circuit 200 may maintain the first common electrode CE1 and the second common electrode CE2 in a floating state. Accordingly, when driven in the normal mode, the birefringent members LC such as liquid crystals arranged inside the condensing lenses CLC are arranged and maintained in a desired or preset alignment direction. In this case, the condensing lenses CLC may maintain a moving direction of the image display light incident from the rear direction thereof, and may pass through the light in the front direction thereof.

As described above, when driven in the normal mode, the display driving circuit 200 may control the condensing lenses CLC to maintain the moving direction of the image display light incident from the rear direction thereof and pass through the light in the front direction thereof. On the other hand, when driven in the privacy mode, the display driving circuit 200 may control the condensing lenses CLC to condense the image display light incident from the rear direction and pass through the light in the front direction.

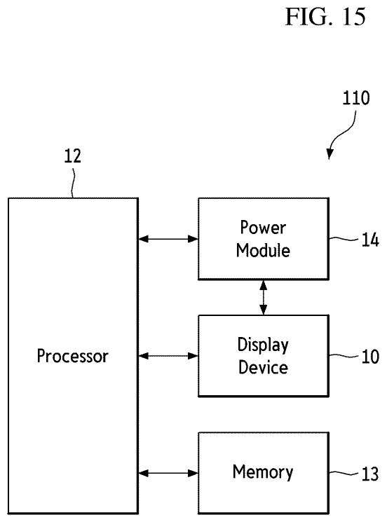

FIG. 15 is a block diagram illustrating an electronic device including a display device according to one example embodiment of the present disclosure.

Referring to FIG. 15, an electronic device 110 according to one example embodiment may include a display device 10, a processor 12, a memory 13, and a power module (or alternatively, a power supply circuitry) 14.

The processor 12 may include at least one of a central processing unit (CPU), an application processor (AP), a graphic processing unit (GPU), a communication processor (CP), an image signal processor (ISP), or a controller.

Data information desired for an operation of the processor 12 or the display device 10 may be stored in the memory 13. When the processor 12 executes an application stored in the memory 13, an image data signal and/or an input control signal is transmitted to the display device 10, and the display device 10 may process the received signal and output image information through a display screen.

The power module 14 may include a power supply module such as a power adapter or a battery device, and a power conversion module converting a power source supplied by the power supply module to generate a power source for the operation of the electronic device 110.

At least one of the respective components of the above-described electronic device 110 may be included in the display device according to the above-described example embodiments. Also, some of the individual modules functionally included in one module may be included in the display device 10, and others thereof may be provided separately from the display device 10. For example, the display device 10 includes a display panel, and the processor 12, the memory 13 and the power module 14 may be provided as other devices in the electronic device 110 not the display device 10.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

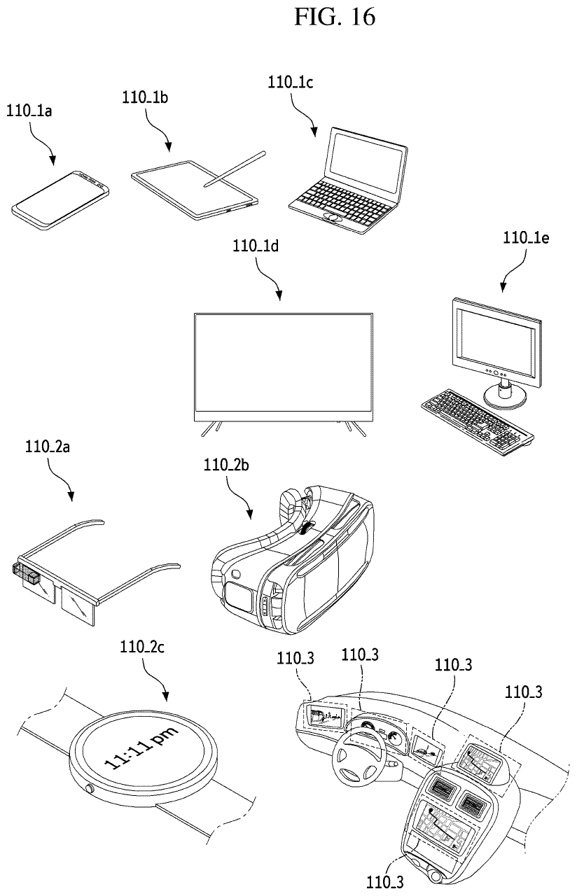

FIG. 16 illustrates schematic diagrams of electronic devices according to various example embodiments.

Referring to FIG. 16, various electronic devices 110 to which the display devices 10 according to the example embodiments of the present disclosure are applied may include not only electronic devices for image display, such as a smart phone 110_1a, a tablet PC 110_1b, a laptop 110_1c, a TV 110_1d, and a desk monitor 110_1e, but also wearable electronic devices including display modules such as smart glasses 110_2a, a head mounted display 110_2b, and a smart watch 110_2c, and a vehicle electronic device 110_3 including display modules such as a vehicle dashboard, a center fascia, a center information display (CID) arranged on the dashboard, and a room mirror display. In addition, the display device 10 may be applied as a display member of a television, a laptop computer, a monitor, an advertising board, or Internet of Things (IOT).

In concluding the detailed description, those skilled in the art will appreciate that many variations and modifications can be made to the example embodiments described above without substantially departing from the principles of the present disclosure. Therefore, the disclosed example embodiments of the disclosure are used in a generic and descriptive sense only and not for purposes of limitation.

What is claimed is:

1. A display device comprising:
a display panel configured to display an image by combining or selecting an image of a relatively wide viewing angle and an image of a relatively narrow viewing angle; and
a display driving circuit configured to control an image display operation of image display pixels included in the display panel,
wherein the display panel includes
a display unit configured to display an image through subpixels for each of a plurality of first unit pixels and subpixels for each of a plurality of second unit pixels,
a light emission direction control layer on the display unit and configured to vary an emission direction of image display light emitted from the display unit to a front surface of the display panel, and
a black matrix on the light emission direction control layer at positions corresponding to a first peripheral area of each of the first unit pixels, a second peripheral area of each of the second unit pixels, and an area between the subpixels for each of the second unit pixels, in a mesh structure.

2. The display device of claim 1, wherein
the light emission direction control layer includes a plurality of condensing lenses and a low refractive polymer material layer,
a first portion of the light emission direction control layer arranged in a front direction of the subpixels for each of the first unit pixels includes only a low refractive polymer material layer, and
a second portion of the light emission direction control layer arranged in a front direction of the subpixels for each of the second unit pixels includes both the condensing lenses and the low refractive polymer material layer covering the condensing lenses is.

3. The display device of claim 2, wherein
the condensing lenses are arranged at positions corresponding to the subpixels for each of the second unit pixels, respectively, the condensing lenses configured to condense the image display light emitted from the subpixels for each of the second unit pixels and emit the image display light in a front direction of the condensing lenses, and
the low refractive polymer material layer is arranged in a planarized state and covers the condensing lenses, the low refractive polymer material layer configured to maintain and emit the image display light condensed from the condensing lenses in the front direction of the condensing lenses.

4. The display device of claim 3, wherein
the subpixels included in each of the first unit pixels and each of the second unit pixels include first to fourth subpixels arranged in a pentile matrix structure, and
the first unit pixels and the second unit pixels are arranged in a pentile matrix structure, alternating with each other in a diagonal direction.

5. The display device of claim 3, wherein
the black matrix is configured to emit the image display light that has passed through the condensing lenses and the low refractive polymer material layer in a front direction of the condensing lenses through an opening of the mesh structure.

6. The display device of claim 2, further comprising:
a first common electrode on a front surface of the display unit and fully covering the display unit; and
a second common electrode on a front surface of the light emission direction control layer and facing the first common electrode with the light emission direction control layer interposed between the first common electrode and the second common electrode.

7. The display device of claim 6, wherein
the condensing lenses are arranged at positions corresponding to the subpixels for each of the second unit pixels, respectively, the condensing lenses including a plurality of birefringent members, and
the low refractive polymer material layer is arranged in a planarized state and covers the condensing lenses, the low refractive polymer material layer configured to maintain and emit the image display light condensed from the condensing lenses in a front direction of a front direction of the condensing lenses.

8. The display device of claim 7, wherein
the condensing lenses include a polymer material including the plurality of birefringent members, and
a cross-section of the condensing lenses is in a convex hemispherical shape, or a polygonal shape of at least one of a triangle, a square, a trapezoid, or a rhombus.

9. The display device of claim 6, wherein
when driven in a normal mode, the display driving circuit is configured to control the image display operation of the subpixels for each of the first unit pixels and each of the second unit pixels by driving all of the subpixels for each of the first unit pixels and each of the second unit pixels, and supply driving voltages of a same magnitude to the first common electrode and the second common electrode or maintains the first common electrode and the second common electrode in a floating state, and
when driven in a privacy mode, the display driving circuit is configured to control the image display operation of the subpixels for each of the second unit pixels by driving the subpixels for each of the second unit pixels, and supply driving voltages of different magnitudes to the first common electrode and the second common electrode, respectively.

10. A display device comprising:
a display panel configured to display an image by combining or selecting an image of a relatively wide viewing angle and an image of a relatively narrow viewing angle;
a display driving circuit configured to control an image display operation of image display pixels included in the display panel; and
a touch driving circuit configured to drive touch electrodes of the display panel and detect touch position coordinates of a touch input device or a user,
wherein the display panel includes
a display unit configured to display an image through subpixels for each of a plurality of first unit pixels and subpixels for each of a plurality of second unit pixels,
a light emission direction control layer on the display unit and configured to vary an emission direction of image display light emitted from the display unit to a front surface of the display panel,
a touch sensing unit including the touch electrodes, being on the light emission direction control layer, and configured to sense a touch position of the touch input device or the user; and
a black matrix on the light emission direction control layer at positions corresponding to a first peripheral area of each of the second unit pixels, a second peripheral area of each of the first unit pixels, and an area between the subpixels for each of the second unit pixels, in a mesh structure.

11. The display device of claim 10, wherein
the light emission direction control layer includes a plurality of condensing lenses and a low refractive polymer material layer,
a first portion of the light emission direction control layer arranged in a front direction of the subpixels for each of the first unit pixels includes only a low refractive polymer material layer, and
a second portion of the light emission direction control layer is arranged in a front direction of the subpixels for each second unit pixel includes both the condensing lenses and the low refractive polymer material layer covering the condensing lenses.

12. The display device of claim 11, wherein
the condensing lenses are arranged at positions corresponding to the subpixels for each of the second unit pixels, respectively, the condensing lenses configured to condense the image display light emitted from the subpixels for each of the second unit pixels, and emit the image display light in a front direction of the condensing lenses, and
the low refractive polymer material layer is arranged in a planarized state and covers the condensing lenses, the low refractive polymer material layer configured to maintain and emit the image display light condensed from the condensing lenses in the front direction of the condensing lenses.

13. The display device of claim 12, wherein
the subpixels included each of the first unit pixels and each of the second unit pixels include first to fourth subpixels arranged in a pentile matrix structure, and
the first unit pixels and the second unit pixels are arranged in a pentile matrix structure, alternating with each other in a diagonal direction.

14. The display device of claim 12, wherein
the black matrix is configured to emit the image display light that has passed through the condensing lenses and the low refractive polymer material layer in a front direction of the condensing lenses through an opening of the mesh structure.

15. The display device of claim 11, further comprising:
a first common electrode on a front surface of the display unit and fully covering the display unit; and
a second common electrode on a front surface of the light emission direction control layer and facing the first common electrode with the light emission direction control layer interposed between the first common electrode and the second common electrode.

16. The display device of claim 15, wherein
the condensing lenses are arranged at positions corresponding to the subpixels for each of the second unit pixels, respectively, the condensing lenses including a plurality of birefringent members, and
the low refractive polymer material layer is arranged in a planarized state and covers the condensing lenses, the low refractive polymer material layer configured to maintain and emit the image display light condensed from the condensing lenses in a front direction of the condensing lenses.

17. The display device of claim 16, wherein
the condensing lenses include a polymer material including the plurality of birefringent members, and
a cross-section of the condensing lenses is in a convex hemispherical shape, or a polygonal shape of at least one of a triangle, a square, a trapezoid, or a rhombus.

18. The display device of claim 15, wherein
when driven in a normal mode, the display driving circuit is configured to control the image display operation of the subpixels for each of the first unit pixels and each of the second unit pixels by driving all of the subpixels for each of the first unit pixels and the second unit pixels, and supply driving voltages of a same magnitude to the first common electrode and the second common electrode or maintain the first common electrode and the second common electrode in a floating state, and
when driven in a privacy mode, the display driving circuit is configured to control the image display operation of the subpixels for each of the second unit pixels by driving the subpixels for each of the second unit pixels, and supply driving voltages of different magnitudes to the first common electrode and the second common electrode, respectively.

19. An electronic device comprising:
a display device configured to display an image;
an image signal processor configured to control an image display timing of the display device; and
power supply circuitry configured to provide a power signal to the display device,
wherein the display device includes
a display panel configured to display an image by combining or selecting an image of a relatively wide viewing angle and an image of a relatively narrow viewing angle; and
a display driving circuit configured to control an image display operation of image display pixels included in the display panel, and
wherein the display panel includes
a display unit configured to display an image through subpixels for each first unit pixel and subpixels for each second unit pixel,
a light emission direction control layer on the display unit and configured to vary an emission direction of image display light emitted from the display unit to a front surface of the display panel, and
a black matrix on the light emission direction control layer at positions corresponding to a first peripheral area of each first unit pixel, a second peripheral area of each second unit pixel, and an area between the subpixels for each second unit pixel.

20. The electronic device of claim 19, wherein the display device is applied as an image display unit to at least one electronic device of an electronic diary, an electronic book, a portable multimedia player (PMP), a navigator, a ultra mobile PC (UMPC), a television, a laptop, a monitor, an advertising board, Internet of Things, a smart phone, a tablet PC, a desk monitor, smart glasses, a head mounted display, a smart watch, a wearable electronic device, or a vehicle dashboard.
